(19) United States
(12) Patent Application Publication
(10) Pub. No.: US 2022/0222009 A1
(43) Pub. Date: Jul. 14, 2022

(54) METHOD AND DEVICE FOR TESTING MEMORY, AND NON-TRANSITORY READABLE STORAGE MEDIUM

(71) Applicant: CHANGXIN MEMORY TECHNOLOGIES, INC., Hefei City (CN)

(72) Inventors: Zhenlin QU, Hefei (CN); Wenxi ZHANG, Hefei (CN)

(21) Appl. No.: 17/502,159

(22) Filed: Oct. 15, 2021

Related U.S. Application Data
(63) Continuation of application No. PCT/CN2021/109055, filed on Jul. 28, 2021.

(30) Foreign Application Priority Data
Jan. 12, 2021 (CN) 202110033604.6

(51) Int. Cl. G06F 3/06

(52) U.S. Cl. CPC G06F 3/0653; G06F 3/0679; G06F 3/0638

(57) ABSTRACT

A method and a device for testing a memory, and a non-transitory readable storage medium are provided. The method for testing the memory includes: executing a memory testing program to perform a memory test on a first area of the memory, the first area being an area that is not occupied by the memory testing program; writing address information of a second area into an external memory of a device, the second area being an area that is occupied by the memory testing program; transferring, after the memory test on the first area is completed, the memory testing program into a partial area of the first area according to the address information of the second area recorded in the external memory; and executing the memory testing program to perform the memory test on the second area.

### CROSS-REFERENCE TO RELATED APPLICATIONS

This is a continuation of International Application No. PCT/CN2021/109055, filed on Jul. 28, 2021, and entitled “Method and Device for Testing a Memory, and Non-transitory Readable Storage Medium”, which claims priority to Chinese patent application No. 202110033604.6, filed on Jan. 12, 2021, and entitled “Method and Device for Testing a Memory, Readable Storage Medium”. The disclosures of International Application No. PCT/CN2021/109055 and Chinese patent application No. 202110033604.6 are hereby incorporated by reference in their entireties.

### TECHNICAL FIELD

The disclosure relates to the field of computers, and particularly to a method and device for testing a memory, and a non-transitory readable storage medium.

### BACKGROUND

A memory is one of the most important components of a computer. All programs in the computer run in the memory. In view of the importance of the memory, the reliability of the memory must be guaranteed during a computer operation process, so that a memory test is essential.

A memory testing program usually needs to rewrite the data into the memory during a process of the memory test. If the memory is already in use, an operation of modifying the used part of the memory during the process of the memory test will cause unpredictable consequences. Therefore, the memory test is generally performed before the memory is used.

However, since the memory testing program itself will occupy a part of the memory, even if the memory is tested before being used, the above testing method may not realize a full coverage test of the memory.

### SUMMARY

According to an aspect of the disclosure, a method for testing a memory is provided, which may include the following operations.

A memory testing program is executed to perform a memory test on a first area of a memory, the first area being an area that is not occupied by the memory testing program.

Address information of a second area is written into an external memory of a device, the second area being an area that is occupied by the memory testing program.

After the memory test on the first area is completed, the memory testing program is transferred into a partial area of the first area according to the address information of the second area recorded in the external memory.

The memory testing program is executed to perform the memory test on the second area.

According to an aspect of the disclosure, a non-transitory readable storage medium on which a computer program is stored is provided, and the above method for testing the memory is implemented when the computer program is executed by a processor.

It is to be understood that the above general descriptions and detail descriptions below are merely exemplary and explanatory, which may not limit the disclosure.

### BRIEF DESCRIPTION OF THE DRAWINGS

The drawings here, which are incorporated in and constitute a part of this description, illustrate embodiments consistent with the disclosure and, together with the description, serve to explain the principles of the disclosure. It is apparent that the drawings described below merely illustrate some embodiments of the disclosure. Those of ordinary skill in the art can obtain other drawings without creative labor on the basis of those drawings.

FIG. 1 schematically shows a schematic flowchart of a method for testing a memory according to an exemplary embodiment of the disclosure.

FIG. 2 schematically shows a first schematic structural diagram of a memory according to an exemplary embodiment of the disclosure.

FIG. 3 schematically shows a second schematic structural diagram of a memory according to an exemplary embodiment of the disclosure.

FIG. 4 schematically shows a flowchart of a method for testing a memory according to an exemplary embodiment of the disclosure.

FIG. 5 schematically shows a block diagram of a device for testing a memory according to an exemplary embodiment of the disclosure.

FIG. 6 schematically shows a module schematic diagram of an electronic device according to an exemplary embodiment of the disclosure.

FIG. 7 schematically shows a schematic diagram of a program product according to an exemplary embodiment of the disclosure.

### DETAILED DESCRIPTION

Exemplary embodiments will now be described more comprehensively with reference to the drawings. However, the exemplary embodiments may be implemented in various forms, and should not be understood to be limited to embodiments elaborated herein. Instead, these embodiments are provided to make the disclosure more comprehensive and complete, and comprehensively communicate the ideas of the exemplary embodiments to those skilled in the art. The same signs in the drawings show same or similar structures, so that detailed description of them will be omitted.

Although the relative terms such as “upper” and “lower” are used in this description to describe the relative relationship of one assembly of the icon to another assembly, these terms used in this description may be only for convenience, for example, the example direction described in the drawings. It should be understood that, if the device of the icon is turned upside down, the assembly described as “upper” will become the assembly described as “lower”. Other relative terms, such as “high”, “low”, “top”, “bottom”, “left”, “right”, etc., may also have similar meanings. When a structure is “upper” of other structures, it may mean that this structure is integrally formed on other structures, or the structure is “directly” on other structures, or the structure is “indirectly” on other structures through another structure.

Terms “one”, “a” and “the” may be used to indicate that there is one or more elements/component distinctions/etc. Terms “include” and “have” are used to indicate the meaning of open inclusion, and it means that there may also be other elements/component distinctions/etc. in addition to the listed elements/component distinctions/etc.

When a computer system is powered on for the first time or reset, the computer system firstly enters a Basic Input Output System (BIOS) with a flash memory on a motherboard to run the BIOS. At the time, the BIOS runs in a Read-Only Memory (ROM). The BIOS will complete the basic hardware initialization according to the process, and then complete the memory initialization. After the memory initialization is completed, the memory may be read and written by the software. In order to avoid problems caused by memory usage confusion, the BIOS has a special memory management program to distinguish and manage the memory according to different properties of the memory. Subsequent programs apply for and release the memory through the memory management program. After the memory initialization is completed, the BIOS will divide the memory into blocks and set properties for each block, which may be provided for the memory management program to use.

During the process of the memory test for the computer system, it may be necessary to use algorithms integrated in the systems (such as an Extensible Firmware Interface (EFI) or a Disk Operating System (DOS)) to read and write a free memory address, so as to detect whether there is a memory address that is invalid or relatively poor. The free memory address here may refer to a memory address not occupied by the system. However, the memory address occupied by the system may not be tested directly, resulting in the failure to realize the full-coverage test of the memory test.

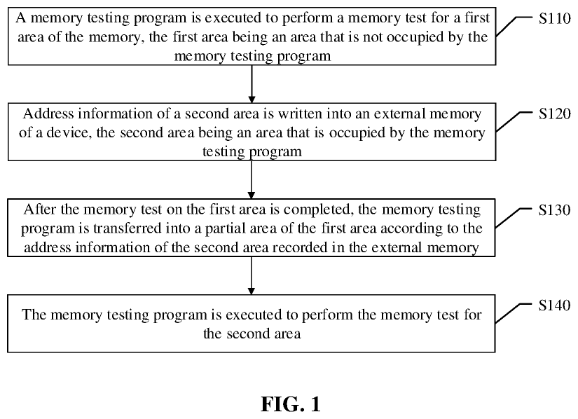

Based on this, the exemplary embodiment provides a method for testing a memory. The method for testing the memory is applicable to computers or other devices that need a memory test when starting up. Referring to FIG. 1, the method for testing the memory includes the following steps of S110 to S140.

At the step of S110, a memory testing program is executed to perform a memory test for a first area of the memory, the first area being an area that is not occupied by the memory testing program.

At the step of S120, address information of a second area is written into an external memory of a device, the second area being an area that is occupied by the memory testing program.

At the step of S130, after the memory test on the first area is completed, the memory testing program is transferred into a partial area of the first area according to the address information of the second area recorded in the external memory.

At the step of S140, the memory testing program is executed to perform the memory test for the second area.

According to the method for testing the memory in the exemplary embodiment, on the one hand, the first area that is not occupied by the memory testing program may be tested at first, and then the memory testing program may be transferred into an occupied area. Therefore, the second area that is occupied by the memory testing program may be tested, so as to realize the full-coverage test for the memory. On the other hand, the address information of the second area may be written into the external memory of the device. Furthermore, the memory testing program may be transferred into the partial area of the first area according to the address information of the second area recorded in the external memory. And therefore, the operation of restarting the system during the transfer can be avoided, thereby reducing the testing time and improving the testing efficiency. Moreover, because the code of the memory testing program runs in the memory, the testing speed will be fast and the running efficiency of the code will be high.

The method for testing the memory in the exemplary embodiment will be further described below.

At the step of S110, the memory testing program may be executed to perform a memory test on the first area of the memory, the first area being an area that is not occupied by the memory testing program.

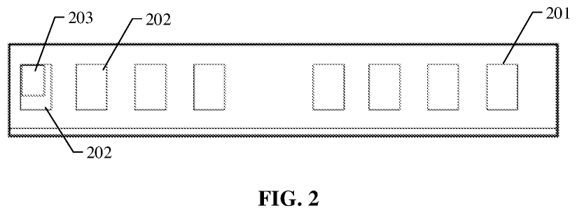

In some exemplary embodiments of the disclosure, as shown in FIG. 2, the memory testing program may be executed in an operating system. Even if the memory test is performed before the memory 201 is used, since the operating system runs in the memory 201, the operating system itself will occupy a part of the memory, and at least the memory testing program running in the operating system will occupy a part of the memory. The first area 202 may be the area that is not occupied by the memory testing program, and the second area 203 may be the area that is occupied by the memory testing program.

After the device is powered on, the BIOS may allocate the second area 203 to the operating system in a conventional manner for use by the memory management program. Then, the BIOS will run in the second area 203, and the operating system will also run in the second area 203. During the memory test, the BIOS may run the memory testing program to test the first area 202. Since the first area 202 is not occupied, the BIOS may safely test the first area 202 of the memory.

According to the method for testing the memory provided in the exemplary embodiment of the disclosure, since the memory testing program is executed in the operating system, that is, the code of the memory testing program runs in the memory, the method for testing the memory will be fast to test the memory and the code will run efficiently.

At the step of S120, the address information of the second area may be written into the external memory of the device.

In the exemplary embodiment of the disclosure, after the BIOS allocates the second area 203 to the operating system, by writing the address information of the second area 203 into the external memory of the device, the address information of the second area 203 may be recorded through the external memory for use in the step of S130.

In the exemplary embodiment of the disclosure, according to the address information of the second area, the memory testing program may be transferred into the area that is not recorded in the memory (i.e., the partial area of the first area that is not occupied by the memory testing program), so as to provide possibility to test the second area.

Here, the operation of transferring the memory testing program into the partial area of the first area may include that a library function in the system may be called through a Central Processing Unit (CPU), and the memory testing program may be mapped into the partial area of the first area with the help of an Input/Output (I/O) interface of the memory and a memory controller. In some embodiments, the library function may include functions such as the Memory Mapping (mmap) function, which will not be specifically limited in the exemplary embodiment. Since the external memory does not occupy the memory, the recorded address information of the second area will not occupy the memory. Therefore, the memory testing program may be transferred directly without restarting the device, so as to reduce the testing time and improving the testing efficiency.

In actual application, the external memory may be selected according to the actual needs. For example, a U disk or a hard disk where the system is arranged may be selected as the external memory for recording the address information of the second area, which will not be limited in the exemplary embodiment.

In the exemplary embodiment, in order to monitor whether the memory test on the first area has been completed, each address that has been tested in the first area may be marked until the memory test on the whole first area is completed. Each address that has been tested in the first area may be marked. On the one hand, it may be possible to determine which addresses in the first area have been marked and which addresses have not been marked during the memory test on the whole first area, so as to provide a basis for the memory test. On the other hand, when the memory testing program is transferred from the second area to the first area, the available address range of the first area may be accurately determined, so as to provide a basis for the transfer. After determining that the memory test for the first area is completed, the step of S130 may be executed.

At the step of S140, the memory testing program may be executed to test the second area.

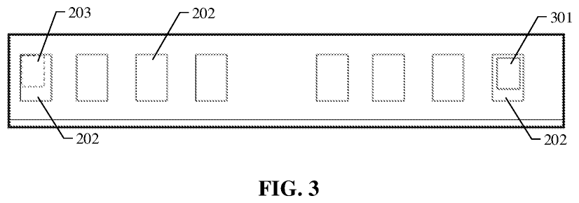

In the exemplary embodiment, referring to FIG. 3, after the memory testing program is transferred into the partial area 301 of the first area 202, the BIOS will run in the partial area 301, and the operating system will also run in the partial area 301. The BIOS may execute the memory testing program to test the second area 203 of the memory. Since the second area 203 is not occupied, the BIOS may safely test the second area 203 of the memory.

As described above, by executing the aforementioned two processes for testing the memory, the memory test performed on the first area and on the second area may be executed respectively, so as to realize the full-coverage test of the memory. Moreover, the address information of the second area may be written into the external memory of the device. Furthermore, the memory testing program may be transferred into the partial area of the first area according to the address information of the second area recorded in the external memory. And therefore, the operation of restarting the system during the transfer can be avoided, thereby reducing the testing time and improving the testing efficiency.

In actual application, when the memory testing program is executed to perform the memory test on the first area of the memory, an address and a length of the first area may be acquired at first, and then the first area of the memory may be tested according to the address and the length of the first area. When the memory testing program is executed to perform the memory test on the second area of the memory, the address and the length of the second area may be acquired at first, and then the second area of the memory may be tested according to the address and the length of the second area.

In actual application, there are many ways to test the memory. In the exemplary embodiment, whether the memory testing program tests the first area or the memory testing program tests the second area, it is a function test to read and write the memory through different pattern algorithms. The different pattern algorithms may include continuous tests for a certain point similar to a row hammer effect, or the different pattern algorithms may include a jump point test, etc., which will not be specially limited in the exemplary embodiment. It should be noted that, the memory test may also include a software memory test, etc. Any memory test that can be implemented by the aforementioned method will fall within the scope of protection of the exemplary embodiment.

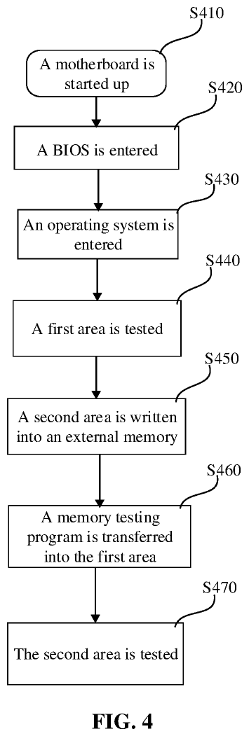

Referring to FIG. 4, a flowchart of a method for testing a memory provided in an exemplary embodiment is shown. As shown in FIG. 4, at the step of S410, a motherboard startup operation may be executed at first; at the step of S420, it may enter the BIOS; at the step of S430, it may enter the operating system by the BIOS; at the step of S440, the memory testing program may be executed to perform the memory test on the first area; at the step of S450, the address information of the second area may be written into the external memory of the device (referred to as writing the second area into the external memory); at the step of S460, after the memory test on the first area is completed, the memory testing program may be transferred into the partial area of the first area (referred to as transferring the memory testing program into the first area); and at the step of S470, the memory testing program may be executed to perform the memory test on the second area.

It should be noted that various steps of the method in the disclosure are described in the accompanying drawings in specific sequence. However, this does not require or imply that these steps have to be executed in the particular order, or that all the steps shown have to be executed to implement desired results. Additionally or alternatively, certain steps may be omitted, a plurality of steps are combined into one step for executing, and/or one step may be decomposed into the plurality of steps for executing, and the like.

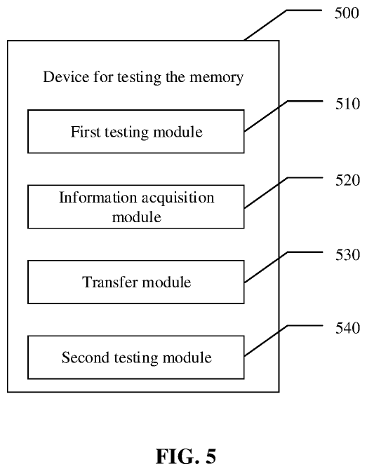

In addition, a device for testing a memory is also provided in an exemplary embodiment. Referring to FIG. 5, the device for testing the memory 500 may include a first testing module 510, an information acquisition module 520, a transfer module 530, and a second testing module 540.

The first testing module 510 is configured to execute a memory testing program to perform a memory test on a first area of the memory, the first area being an area that is not occupied by the memory testing program.

The information acquisition module 520 is configured to write address information of a second area into an external memory of a device, the second area being an area that is occupied by the memory testing program.

The transfer module 530 is configured to transfer, after the memory test for the first area is completed, the memory testing program into a partial area of the first area according to the address information of the second area recorded in the external memory.

The second testing module 540 is configured to execute the memory testing program to perform the memory test on the second area.

According to the method for testing the memory provided in the exemplary embodiment of the disclosure, since the memory testing program is executed in the operating system, that is, the code of the memory testing program runs in the memory, the method for testing the memory will be fast to test the memory and the code will run efficiently.

In the exemplary embodiment of the disclosure, according to the address information of the second area, the memory testing program may be transferred into the area that is not recorded in the memory (i.e., the partial area of the first area that is not occupied by the memory testing program), so as to provide possibility to test the second area.

Here, the operation of transferring the memory testing program into the partial area of the first area may include that the memory testing program may be mapped into the partial area of the first area through a memory interface. Moreover, since the external memory does not occupy the memory, the recorded address information of the second area will not occupy the memory. Therefore, the memory testing program may be transferred directly without restarting the device, so as to reduce the testing time and improve the testing efficiency.

In actual application, the external memory may be selected according to the actual needs. For example, a U disk or a hard disk where the system is arranged may be selected as the external memory for recording the address information of the second area, which will not be limited in the exemplary embodiment.

In the exemplary embodiment, in order to monitor whether the memory test for the first area has been completed, the information acquisition module 520 may further be configured to mark each address that has been tested in the first area until the memory test on the whole first area is completed. After determining that the memory test on the first area is completed, it may enter the transfer module 530.

As described above, by executing the aforementioned two processes for testing the memory, the memory test performed on the first area and on the second area may be executed respectively, so as to realize the full coverage test of the memory. Moreover, the address information of the second area may be written into the external memory of the device. Furthermore, the memory testing program may be transferred into the partial area of the first area according to the address information of the second area recorded in the external memory. And therefore, the operation of restarting the system during the transfer can be avoided, thereby reducing the testing time and improving the testing efficiency.

In actual application, when the memory testing program is executed to perform the memory test on the first area of the memory, an address and a length of the first area may be acquired at first, and then the first area of the memory may be tested according to the address and the length of the first area. When the memory testing program is executed to perform the memory test on the second area of the memory, the address and the length of the second area may be acquired at first, and then the second area of the memory may be tested according to the address and the length of the second area.

In actual application, there are many ways to test the memory. In the exemplary embodiment, whether the memory testing program tests the first area or the memory testing program tests the second area, it is a function test to read and write the memory through different pattern algorithms. The different pattern algorithms may include continuous tests for a certain point similar to a row hammer effect, or the different pattern algorithms may include a jump point testing, etc., which will not be specially limited in the exemplary embodiment. It should be noted that, the memory test may also include a software memory test, etc. Any memory test that can be implemented by the aforementioned method will fall within the scope of protection of the exemplary embodiment.

The specific details of each of the virtual modules of the device 500 for testing the memory have been described in detail in the corresponding method for testing the memory, so that it will not be elaborated here.

It should be noted that, although a plurality of modules or units of the device for testing the memory are mentioned in the foregoing detailed descriptions, but this division is not mandatory. Actually, according to the embodiments of the disclosure, the foregoing described features and functions of two or more modules or units may be embodied in one module or one unit. On the contrary, the foregoing described features and functions of one module or one unit may further be embodied by a plurality of modules or units.

Moreover, the drawings are merely schematic descriptions of processes included in the methods in the exemplary embodiments of the disclosure, but not for limitation. It should be easily understood that the processes shown in the aforementioned drawings do not show or limit the time sequence of these processes. Moreover, it may be also to be easily understood that these processes may be executed synchronously or asynchronously in a plurality of modules.

In the exemplary embodiment of the disclosure, an electronic device capable of achieving the above method is also provided.

Those skilled in the art may understand that various aspects of the disclosure may be implemented as systems, methods or program products. Therefore, various aspects of the disclosure may be specifically implemented in the following forms: a complete hardware embodiment, a complete software embodiment (including firmware, microcode, etc.), or a combination of hardware and software, which may be collectively referred to as “circuit”, “module” or “system”.

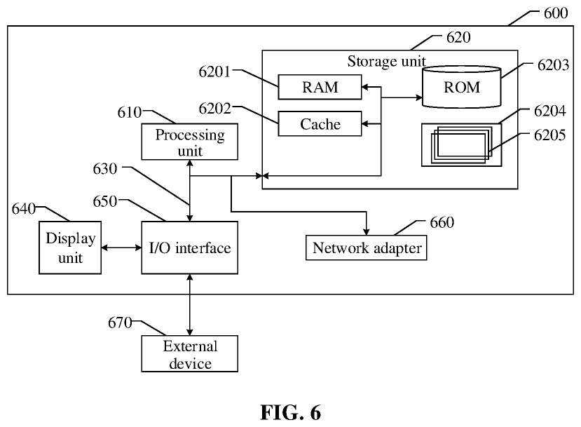

The electronic device 600 according to the embodiment of the disclosure will be described below with reference to FIG. 6. The electronic device 600 shown in FIG. 6 is only an example and should not form any limit to the functions and scope of use of the embodiments of the disclosure.

As shown in FIG. 6, the electronic device 600 may be represented in the form of a general computing device. The components of the electronic device 600 may include, but are not limited to, at least one processing unit 610, at least one storage unit 620, a bus 630 connecting different system components (including the storage unit 620 and the processing unit 610), and a display unit 640.

The storage unit 620 may be configured to store a program code that may be executed by the processing unit 610, so that the processing unit 610 can execute the steps according to various exemplary embodiments of the disclosure described in the aforementioned “exemplary methods” section of the description. For example, as shown in FIG. 1, the processing unit 610 may be configured to: execute the memory testing program to perform a memory test on the first area of the memory, the first area being an area that is not occupied by the memory testing program in the step of S110, write the address information of the second area into the external memory of the device, the second area being the area that is occupied by the memory testing program in the step of S120, transfer, after the memory test for the first area is completed, the memory testing program into a partial area of the first area according to the address information of the second area recorded in the external memory, and execute the memory testing program to perform the memory test on the second area in the step of S140.

The storage unit 620 may include a readable medium in the form of a volatile storage unit, such as a Random Access Memory (RAM) 6201 and/or a cache storage unit 6202, and may further include a Read-Only Memory (ROM) 6203.

The storage unit 620 may also include a program/utility 6204 with a set (at least one) of program modules 6205 that include, but not limited to, an operating system, one or more application programs, other program modules and program data. Each or a certain combination of these examples may include an implementation of a network environment.

The bus 630 may represent one or more of several types of bus structures, including a storage unit bus or a storage unit controller, a peripheral bus, a graphics acceleration port, a processing unit, or a local bus using any of a variety of bus structures.

The electronic device 600 may also communicate with one or more external devices 670 (a keyboard, a pointing device, a Bluetooth device, etc.), with one or more devices that enable a user to interact with the electronic device 600, and/or with any device that enables the electronic device 600 to communicate with one or more other computing devices (a router, a modem, etc.). This communication may be performed through an I/O interface 650. Moreover, the electronic device 600 may also communicate with one or more networks, such as a Local Area Network (LAN), a Wide Area Network (WAN), and/or a public network, such as the Internet, through a network adapter 660. As shown in the figure, the network adapter 660 communicates with other modules of the electronic device 600 through the bus 630. It should be understood that, although not shown in the figure, other hardware and/or software modules may be used in combination with the electronic device 600, including, but not limited to, a microcode, a device driver, a redundant processing unit, an external disk drive array, a Redundant Arrays of Independent Disk (RAID) system, a tape drive, data backup storage system, etc.

Through the above descriptions about the embodiments, it is easily understood by those skilled in the art that the exemplary embodiments described here may be implemented by software, or may be implemented by combining the software and necessary hardware. Therefore, the technical solution according to the embodiments of the disclosure may be embodied in form of a software product, and the software product may be stored in a non-volatile storage medium (which may be a CD-ROM, a U disk, a mobile hard disk, etc.) or a network, including a plurality of instructions enabling a computing device (which may be a personal computer, a server, a terminal device, a network device, etc.) to execute the method according to the embodiments of the disclosure.

In the exemplary embodiment of the disclosure, a non-transitory readable storage medium is also provided, on which a program product capable of achieving the above method in the description is stored. In some possible embodiments, various aspects of the disclosure may also be implemented in the form of a program product including a program code for causing the terminal device to perform the steps according to various exemplary embodiments of the disclosure described in the above “exemplary methods” section of the specification when the program product is running on the terminal device.

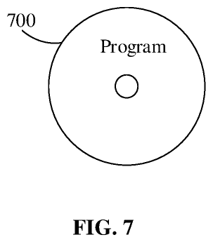

Referring to FIG. 7, a program product 700 for achieving the above method according to an embodiment of the disclosure is described, which may adopt a portable Compact Disk Read Only Memory (CD-ROM) and include a program code, and may run on a terminal device, such as a personal computer. However, the program product of the disclosure is not limited to this. In the file, the non-transitory readable storage medium may be any physical medium including or storing a program, and the program may be used by or in combination with an instruction execution system, device, or apparatus.

The program product may adopt any combination of one or more non-transitory readable mediums. The non-transitory readable medium may be a readable signal medium or a readable storage medium. The non-transitory readable storage medium may be, but not limited to, for example, an electrical, magnetic, optical, electromagnetic, infrared, or semiconductor system, device, or apparatus, or any combination thereof. More specific examples (a non-exhaustive list) of the non-transitory readable storage medium may include an electrical connector with one or more wires, a portable disk, a hard disk, a RAM, a ROM, an Erasable Programmable ROM (EPROM or a flash memory), an optical fiber, a CD-ROM, an optical storage device, a magnetic storage device, or any proper combination thereof.

The computer readable signal medium may include a data signal in a baseband or propagated as part of a carrier, a readable program code being born therein. A plurality of forms may be adopted for the propagated data signal, including, but not limited to, an electromagnetic signal, an optical signal, or any proper combination. The readable signal medium may also be any readable medium except the non-transitory readable storage medium, and the readable medium may send, propagate, or transmit a program configured to be used by or in combination with an instruction execution system, device, or apparatus.

The program code in the readable medium may be transmitted with any proper medium, including, but not limited to, radio, a wire, an optical cable, Radio Frequency (RF), etc. or any proper combination thereof.

The program code for executing the operations of the disclosure may be written in any combination of one or more programming languages, including object-oriented programming languages such as Java, C++, etc., and conventional procedural programming languages such as “C” language or similar programming languages. The program code may be executed completely on a user computing device, partially on a user device, as a separate software package, partially on a user computing device, partially on a remote computing device, or completely on a remote computing device or server. In the case of the remote computing device, the remote computing device may be connected to a user computing device through any kind of network, including a LAN or a WAN, or may be connected to an external computing device (such as through the Internet using an Internet service provider).

Moreover, the drawings are merely schematic descriptions of processes included in the methods in the exemplary embodiments of the disclosure, but not for limitation. It is to be easily understood that the processes shown in the above drawings do not show or limit the time sequence of these processes. Moreover, it is also to be easily understood that these processes may be executed synchronously or asynchronously in a plurality of modules.

After considering the specification and practicing the disclosure here, those skilled in the art will easily thick about other embodiments of the disclosure. The disclosure is intended to cover any transformations, uses or adaptive variations of the disclosure, and these transformations, uses or adaptive variations follow the general principle of the disclosure, and include common general knowledge or conventional technical means undisclosed in the technical field of the disclosure. The specification and the embodiments are only considered as examples, and the practical scope and spirit of the disclosure are pointed out by the claims.

It should be understood that the disclosure is not limited to the precise structures described above and shown in the drawings, and various modifications and variations may be made without departing from the scope thereof. The scope of the disclosure is only defined by the appended claims.

1. A method for testing a memory, comprising:
executing a memory testing program to perform a memory test on a first area of the memory, the first area being an area that is not occupied by the memory testing program;
writing address information of a second area into an external memory of a device, the second area being an area that is occupied by the memory testing program;
transferring, after the memory test on the first area is completed, the memory testing program into a partial area of the first area according to the address information of the second area recorded in the external memory; and
executing the memory testing program to perform the memory test on the second area.

2. The method of claim 1, wherein the transferring the memory testing program into the partial area of the first area according to the address information of the second area recorded in the external memory comprises:
mapping the memory testing program into the partial area of the first area through a library function in a system, according to the address information of the second area recorded in the external memory.

3. The method of claim 1, before the memory test on the first area is completed, further comprising:
marking each address that has been tested in the first area until the memory test on the whole first area is completed.

4. The method of claim 1, wherein the external memory comprises a U disk or a hard disk where a system is arranged.

5. The method of claim 1, wherein the executing the memory testing program to perform the memory test on the first area of the memory comprises:
acquiring, through the memory testing program, an address and a length of the first area, and testing, through the memory testing program, the first area of the memory according to the address and the length of the first area.

6. The method of claim 1, wherein the executing the memory testing program to perform the memory test on the second area comprises:
acquiring, through the memory testing program, an address and a length of the second area, and testing, through the memory testing program, the second area of the memory according to the address and the length of the second area.

7. The method of claim 1, wherein the memory test comprises a function test for reading and writing the memory through different pattern algorithms.

8. A device for testing a memory, comprising:
a processor; and
a storage medium, configured to store one or more programs executable by the processor,
wherein the processor is configured to:
execute a memory testing program to perform a memory test on a first area of the memory, the first area being an area that is not occupied by the memory testing program;
write address information of a second area into an external memory of a device, the second area being an area that is occupied by the memory testing program;
transfer, after the memory test on the first area is completed, the memory testing program into a partial area of the first area according to the address information of the second area recorded in the external memory; and
execute the memory testing program to perform the memory test on the second area.

9. The device of claim 8, wherein the processor is further configured to:
map the memory testing program into the partial area of the first area through a memory interface, according to the address information of the second area recorded in the external memory.

10. The device of claim 8, wherein before the memory test on the first area is completed, the processor is further configured to mark each address that has been tested in the first area until the memory test on the whole first area is completed.

11. The device of claim 8, wherein the external memory comprises a U disk or a hard disk where a system is arranged.

12. The device of claim 8, wherein the processor is further configured to:
acquire, through the memory testing program, an address and a length of the first area, and test, through the memory testing program, the first area of the memory according to the address and the length of the first area.

13. The device of claim 8, wherein the processor is further configured to:
acquire, through the memory testing program, an address and a length of the second area, and test, through the memory testing program, the second area of the memory according to the address and the length of the second area.

14. The device of claim 8, wherein the memory test comprises a function test for reading and writing the memory through different pattern algorithms.

15. A non-transitory readable storage medium, on which a computer program is stored, wherein when the computer program is executed by a processor, a method for testing a memory is implemented, and the method comprising:
executing a memory testing program to perform a memory test on a first area of the memory, the first area being an area that is not occupied by the memory testing program;
writing address information of a second area into an external memory of a device, the second area being an area that is occupied by the memory testing program;
transferring, after the memory test on the first area is completed, the memory testing program into a partial area of the first area according to the address information of the second area recorded in the external memory; and
executing the memory testing program to perform the memory test on the second area.

16. The non-transitory readable storage medium of claim 15, wherein the transferring the memory testing program into the partial area of the first area according to the address information of the second area recorded in the external memory comprises:
mapping the memory testing program into the partial area of the first area through a library function in a system, according to the address information of the second area recorded in the external memory.

17. The non-transitory readable storage medium of claim 15, before the memory test on the first area is completed, the method further comprises:
marking each address that has been tested in the first area until the memory test on the whole first area is completed.

18. The non-transitory readable storage medium of claim 15, wherein the executing the memory testing program to perform the memory test on the first area of the memory comprises:
acquiring, through the memory testing program, an address and a length of the first area, and testing, through the memory testing program, the first area of the memory according to the address and the length of the first area.

19. The non-transitory readable storage medium of claim 15, wherein the executing the memory testing program to perform the memory test on the second area comprises:
acquiring, through the memory testing program, an address and a length of the second area, and testing, through the memory testing program, the second area of the memory according to the address and the length of the second area.

20. The non-transitory readable storage medium of claim 15, wherein the memory test comprises a function test for reading and writing the memory through different pattern algorithms.
